(19) United States
(12) Patent Application Publication
(10) Pub. No.: US 2017/0256771 A1
(43) Pub. Date: Sep. 7, 2017

(54) FLEXIBLE CIRCUIT FOR VEHICLE BATTERY

(71) Applicant: Faraday&Future Inc., Gardena, CA (US)

(72) Inventors: Kameron Fraige Saad Buckhout, Inglewood, CA (US); William Alan Beverley, Lakewood, CA (US); David Tarlau, Torrance, CA (US)

(21) Appl. No.: 15/060,381

(22) Filed: Mar. 3, 2016

(51) Int. Cl. H01M 2/20; H01M 2/24; H05K 1/18; H01M 10/48; H01M 10/04; H01M 2/30; H01M 10/42

(52) U.S. Cl. CPC H01M 2/206; H01M 2/305; H01M 2/24; H01M 10/4257; H01M 10/482; H01M 10/04; H05K 1/181; H01M 2220/20; H05K 2201/10037; H05K 2201/05

(57) ABSTRACT

Disclosed herein are battery systems for electric vehicles. An electric vehicle may include a first battery. The first battery may be configured to power various low voltage systems. For example, the first battery may provide the power to start the vehicle. The vehicle may include a second battery. The second battery may be configured to power one or more electric motors for propelling the vehicle. The first battery may supply power necessary to engage and/or access the power stored in the second battery. The first battery may include a flexible circuit configured to electrically connect a plurality of battery cells in series and/or in parallel. The flexible circuit may be configured to contact each cell at a plurality of points to ensure that the cells remain connected during the operation of the vehicle.

### CROSS-REFERENCE TO RELATED APPLICATIONS

The present application is related to Attorney Docket No. FARA.021A, entitled “VEHICLE BATTERY HEATING SYSTEM,” Attorney Docket No. FARA.022A, entitled “BUS BAR AND PCB FOR VEHICLE BATTERY,” and Attorney Docket No. FARA.023A, entitled “ELECTRIC VEHICLE BATTERY,” filed on the same day as the present application. Each of the above-referenced applications is hereby expressly incorporated by reference in its entirety and for all purposes.

### BACKGROUND

Field

This disclosure relates to vehicle battery systems, and more specifically to systems and methods for transferring electricity to, from, and within vehicle batteries using flexible circuits.

Description of the Related Art

Electric vehicles, hybrid vehicles, and internal combustion engine vehicles generally contain a low voltage automotive battery to provide power for starting the vehicle and/or to provide power for various other electrically powered systems. Automotive batteries typically provide approximately 12 volts, and may range up to 16 volts. Such batteries are typically lead-acid batteries. In electric or hybrid vehicles, a low voltage automotive battery may be used in addition to higher voltage powertrain batteries.

### SUMMARY

The systems and methods of this disclosure each have several innovative aspects, no single one of which is solely responsible for its desirable attributes. Without limiting the scope as expressed by the claims that follow, its more prominent features will now be discussed briefly.

Disclosed herein are battery systems for electric vehicles. An electric vehicle may include a first battery. The first battery may be configured to power various low voltage systems. For example, the first battery may provide the power to start the vehicle. The vehicle may include a second battery. The second battery may be configured to power one or more electric motors for propelling the vehicle. The first battery may supply power necessary to engage and/or access the power stored in the second battery. The first battery may include a flexible circuit configured to electrically connect a plurality of battery cells in series and/or in parallel. The flexible circuit may be configured to contact each cell at a plurality of points to ensure that the cells remain connected during the operation of the vehicle.

Some implementations for a low voltage battery for an electric vehicle include a housing. A plurality of rechargeable electrochemical cells may be disposed within the housing. The electrochemical cells may have a top side and a bottom side. The top side may have at least one positive terminal and at least one negative terminal disposed thereon. A positive bus bar disposed and a negative bus bar may be disposed within the housing. The positive bus bar may include a positive terminal post in electrical contact with the positive bus bar and extending through the housing. A negative terminal post may be in electrical contact with the negative bus bar and extending through the housing. A flex circuit may be disposed within the housing. The flex circuit may include a first conductive surface in electrical contact with the positive bus bar and the positive terminal of at least one of the electrochemical cells. The flex circuit may include a second conductive surface in electrical contact with the negative bus bar and the negative terminal of at least one of the electrochemical cells. The first and second conductive surfaces may be insulated from electrical contact with one another. Battery monitoring circuitry may also be disposed within the housing. The monitoring circuitry may be configured to measure a voltage drop between the first conductive surface and the second conductive surface.

Some implementations include a flexible circuit for a vehicle battery. The circuit may include at least a first conductive layer and a second conductive layer that are electrically separated by an insulating layer. At least one opening may be located through the first conductive layer. The opening may be sized and/or shaped to provide access to at least a portion of a positive terminal of an electrochemical cell. A plurality of electrically conductive positive contact arms may extend from the first conductive surface and into the at least one opening in the first conductive layer. The positive contact arms may include at least one positive contact point configured to contact and electrically connect to the positive terminal of the electrochemical cell. At least one opening may extend through the second conductive layer. The opening may be sized and/or shaped to provide access to at least a portion of a negative terminal of an electrochemical cell. A plurality of electrically conductive negative contact arms may extend from the second conductive surface and into the at least one opening in the second conductive layer. The negative contact arms may include at least one negative contact point configured to contact and electrically connect to the negative terminal of the electrochemical cell. One or more positive contact arms may include a first end and a second end. The first end may extend from an edge that defines at least one of the openings in the first conductive layer. The second end may be configured to contact and electrically connect the positive terminal of the electrochemical cell. The second ends may include a plurality of contact points configured to contact and electrically connect to the positive terminal of the electrochemical cell. In some aspects, the second ends branch into a Y-shaped portion having two contact points configured to contact and electrically connect to the positive terminal of the electrochemical cell. The negative contact arms may also include a first end and a second end. The first end may extend from an edge that defines at least one of the openings in the second conductive layer. The second ends of the negative contact arms may include a plurality of contact points configured to contact and electrically connect to the negative terminal of the electrochemical cell. In some aspects, the second ends of the negative contact arms branch into a Y-shaped portion having at least two contact points configured to contact and electrically connect to the negative terminal of the electrochemical cell. The second ends may be configured to contact and electrically connect to the negative terminal of the electrochemical cell. The openings in the first and second conducting layers may overlap and or be disposed at least partially or fully on top of one another. The second conductive surface may include at least two negative openings for each electrochemical cell.

In some implementations, a flexible circuit for a vehicle battery may include at least a first conductive layer and a second conductive layer that are electrically separated by an insulating layer. At least one opening may be disposed in the first conductive layer. The first opening may be sized and shaped to provide access to at least a portion of a positive terminal of an electrochemical cell. The opening may extend through a second conductive layer and/or an insulating layer. A plurality of electrically conductive positive contact arms may extend from the first conductive surface and into the at least one opening. The positive contact arms may include at least one positive contact point configured to contact and electrically connect at least one positive terminal of an electrochemical cell. In some aspects, the positive contact arms include two or more positive contact points. The circuit may also include at least one opening in the second conductive layer. The opening in the second conductive layer may be sized and shaped to provide access to at least a portion of a negative terminal of an electrochemical cell. The opening may extend through the first conductive layer and/or an insulating layer. A plurality of electrically conductive negative contact arms may extend from the second conductive surface and into the at least one opening in the second conductive layer. The negative contact arms may include at least one negative contact point configured to contact and electrically connect to at least one negative terminal of the electrochemical cell. In some aspects, the negative contact arms include two or more negative contact points.

In some implementations, a method of manufacturing a vehicle battery may include one or more of the following steps. For example, the method may include placing a plurality of rechargeable electrochemical cells into a first housing portion. The electrochemical cells may have a top side and a bottom side. The top side may have at least one positive terminal and at least one negative terminal disposed thereon. The method may include securing a positive bus bar and a negative bus bar to a second housing portion that is different from the first housing portion. The positive bus bar may be connected to a positive terminal post extending through the second housing portion. The negative bus bar may be connected to a negative terminal post extending through the second housing portion. The method may include electrically connecting the cells by placing a flex circuit against the top side of the cells. The flex circuit may include a first conductive surface in electrical contact with the positive terminal of at least one of the electrochemical cells. A second conductive surface may be in electrical contact with the negative terminal of at least one of the electrochemical cells. The second conductive surface may be insulated from electrical contact with the first conductive surface. The method may include contacting the first and second housing portions such that the positive bus bar contacts and forms a direct electrical connection with the first conductive surface. The negative bus bar may contact and form a direct electrical connection with the second conductive surface. The method may include sealing the first portion to the second portion. The method may include securing the flex circuit in place against the top side of the cells. Securing the flex circuit in place may be accomplished by applying an adhesive compound, plastic welding and/or welding at least one positive conducting arm to a positive terminal and at least one negative conducting arm to a negative terminal.

### BRIEF DESCRIPTION OF THE DRAWINGS

The above-mentioned aspects, as well as other features, aspects, and advantages of the present technology will now be described in connection with various implementations, with reference to the accompanying drawings. The illustrated implementations are merely examples and are not intended to be limiting. Throughout the drawings, similar symbols typically identify similar components, unless context dictates otherwise.

FIG. 1 is a top perspective view of an assembled low voltage automotive battery in accordance with an exemplary embodiment.

FIG. 2 is a cross sectional view of an assembled battery of FIG. 1.

FIG. 3 is an exploded view of an automobile battery of FIG. 1.

FIG. 4 is a perspective view of the lower portion of the battery of FIG. 1 as prepared for final assembly in accordance with an exemplary embodiment.

FIG. 5 is a perspective view of the upper portion of the battery of FIG. 1 prepared for final assembly in accordance with an exemplary embodiment. When assembled, the top portion may be inverted from its position shown in FIG. 5 and placed on top of the lower portion shown in FIG. 4 to form an assembled housing as shown in FIG. 3.

FIG. 6 is a partial cutaway perspective view of the battery of FIG. 1 illustrating the primary electrical connections of the battery in accordance with an exemplary embodiment.

FIG. 7A and FIG. 7B are top views of two conductive layers of a flex circuit in accordance with an exemplary embodiment.

FIG. 7C is a top view of an assembled flex circuit including the conductive layers of FIGS. 7A and 7B and insulating layers in accordance with an exemplary embodiment.

FIG. 7D is an enlarged top view of a portion of the assembled flex circuit of FIG. 7C in accordance with an exemplary embodiment.

FIG. 8A is a top perspective view of a portion of the assembled flex circuit of FIG. 7C showing the electrical connections between the flex circuit and an electrochemical cell in accordance with an exemplary embodiment.

FIG. 8B is an exploded top perspective view of the flex circuit portion of FIG. 8A showing the electrical connections between the flex circuit and an electrochemical cell in accordance with an exemplary embodiment.

### DETAILED DESCRIPTION OF THE PREFERRED EMBODIMENT

The following description is directed to certain implementations for the purpose of describing the innovative aspects of this disclosure. However, a person having ordinary skill in the art will readily recognize that the teachings herein can be applied in a multitude of different ways. In some implementations, the word “battery” or “batteries” will be used to describe certain elements of the embodiments described herein. It is noted that “battery” does not necessarily refer to only a single battery cell. Rather, any element described as a “battery” or illustrated in the Figures as a single battery in a circuit may equally be made up of any larger number of individual battery cells and/or other elements without departing from the spirit or scope of the disclosed systems and methods.

Reference may be made throughout the specification to “12 volt” power systems or sources. It will be readily apparent to a person having ordinary skill in the art that the phrase “12 volt” in the context of automotive electrical systems is an approximate value referring to nominal 12 volt power systems. The actual voltage of a “12 volt” system in a vehicle may fluctuate as low as roughly 4-5 volts and as high as 16-17 volts depending on engine conditions and power usage by various vehicle systems. Such a power system may also be referred to as a “low voltage” system. Some vehicles may use two or more 12 volt batteries to provide higher voltages. Thus, it will be clear that the systems and methods described herein may be utilized with battery arrangements in at least the range of 4-34 volts without departing from the spirit or scope of the systems and methods disclosed herein.

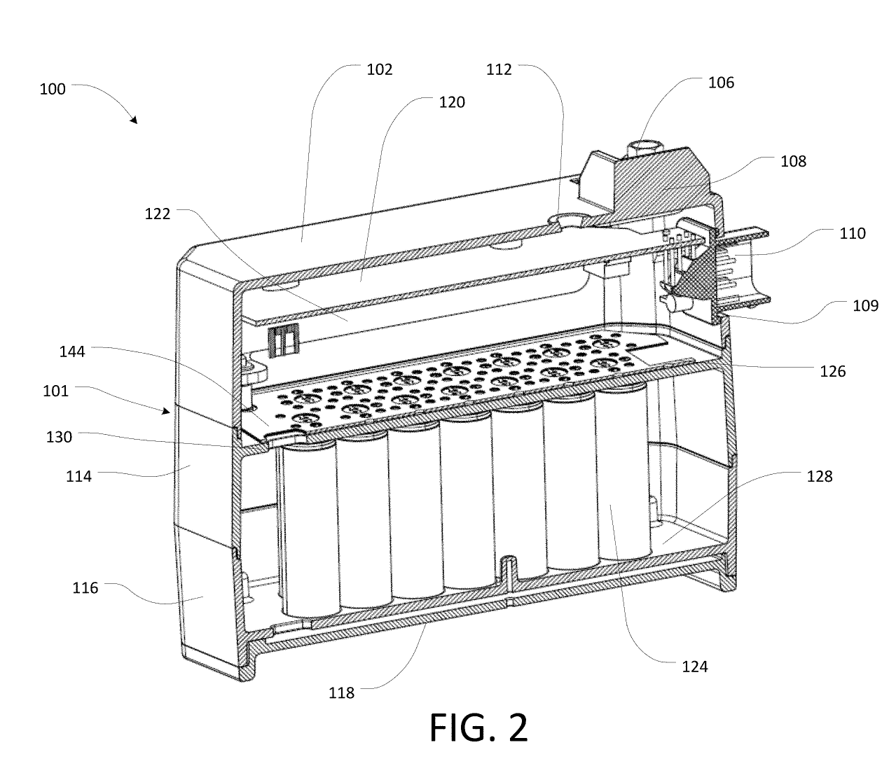

To assist in the description of various components of the battery systems, the following coordinate terms are used (see, e.g., FIGS. 2-5). A “longitudinal axis” is generally parallel to the longest dimension of the battery housing embodiments depicted. A “lateral axis” is normal to the longitudinal axis. A “transverse axis” extends normal to both the longitudinal and lateral axes. For example, the cross sectional view of FIG. 2 depicts a plurality of cylindrical cells; each cell is oriented parallel to the transverse axis, while the cells are oriented in a row of seven cells along a line parallel to the longitudinal axis.

In addition, as used herein, “the longitudinal direction” refers to a direction substantially parallel to the longitudinal axis, “the lateral direction” refers to a direction substantially parallel to the lateral axis, and the “transverse direction” refers to a direction substantially parallel to the transverse axis.

The terms “upper,” “lower,” “top,” “bottom,” “underside,” “top side,” “above,” “below,” and the like, which also are used to describe the present battery systems, are used in reference to the illustrated orientation of the embodiment. For example, as shown in FIG. 2, the term “top side” may be used to describe the surface of the battery housing containing the positive and negative terminal posts, while the term “bottom” may be used to describe the location of the baseplate.

Traditional gasoline powered cars typically include a low voltage SLI (starting, lighting, ignition) battery. Similarly, electric vehicles may include a low voltage SLI battery along with a high voltage battery system having significant energy storage capacity and suitable for powering electric traction motors. The low voltage battery may be necessary to provide the startup power, power an ignition, close a high voltage battery contactor, and/or power other low voltage systems (e.g. lighting systems, electronic windows and/or doors, trunk release systems, car alarm systems, and the like).

In addition to powering the vehicle's propulsion motors, the high voltage batteries' output may be stepped down using one or more DC-to-DC converters to power some or all of the other vehicle systems, such as interior and exterior lights, power assisted braking, power steering, infotainment, automobile diagnostic systems, power windows, door handles, and various other electronic functions when the high voltage batteries are engaged.

High voltage batteries may be connected to or isolated from other vehicle circuitry by one or more magnetic contactors. Normally open contactors require a power supply in order to enter or remain in the closed circuit position. Such contactors may be configured to be in the open (disconnected) configuration when powered off to allow the high voltage batteries to remain disconnected while the vehicle is powered off. Thus, on startup, a small power input is required to close at least one contactor of the high voltage battery pack. Once a contactor is closed, the high voltage batteries may supply the power required to keep the contactor(s) closed and/or supply power to other vehicle systems.

Particular embodiments of the subject matter described by this disclosure can be implemented to realize one or more the following potential advantages. Rather than using a traditional lead-acid automobile battery, the present allows for a smart rechargeable battery that does not require a fluid filled container. In some aspects, one or more individual cells in a housing may be monitored individually or in subsets. In some aspects, additional individual cells may be provided within the housing such that the connected cells can provide more voltage than necessary to compensate for the potential of the loss of one or more of the cells. The disclosed design may be easier and/or less expensive to manufacture. For example, the number of manufacturing steps may be minimized and the labor may be simplified and/or made more efficient. For example, two halves of a battery housing may be assembled separately and electrical components may later be coupled together in one final step when the two housing halves are combined. Such a construction may minimize the number of sealing steps while sensitive parts are contained within the housing. A desiccant may be provided to remove excess moisture in the housing in order to further protect the electric components and/or cells within the housing. A valve may help prevent unsafe pressures from building up within the housing. In some aspects, the housing may be designed such that the parts inside the housing are inhibited from moving excessively and/or vibrating excessively while a vehicle is operated. A flex circuit may be used to electrically connect the plurality of cells. Such a circuit may be compact, lightweight, and/or able to withstand the forces and/or vibrations experienced by a vehicle while driving.

These, as well as, other various aspects, components, steps, features, objects benefits, and advantages will now be described with reference to specific forms or embodiments selected for the purposes of illustration. It will be appreciated that the spirit and scope of the cassettes disclosed herein is not limited to the selected forms. Moreover, it is to be noted that the figures provided herein are not drawn to any particular proportion or scale, and that many variations can be made to the illustrated embodiments.

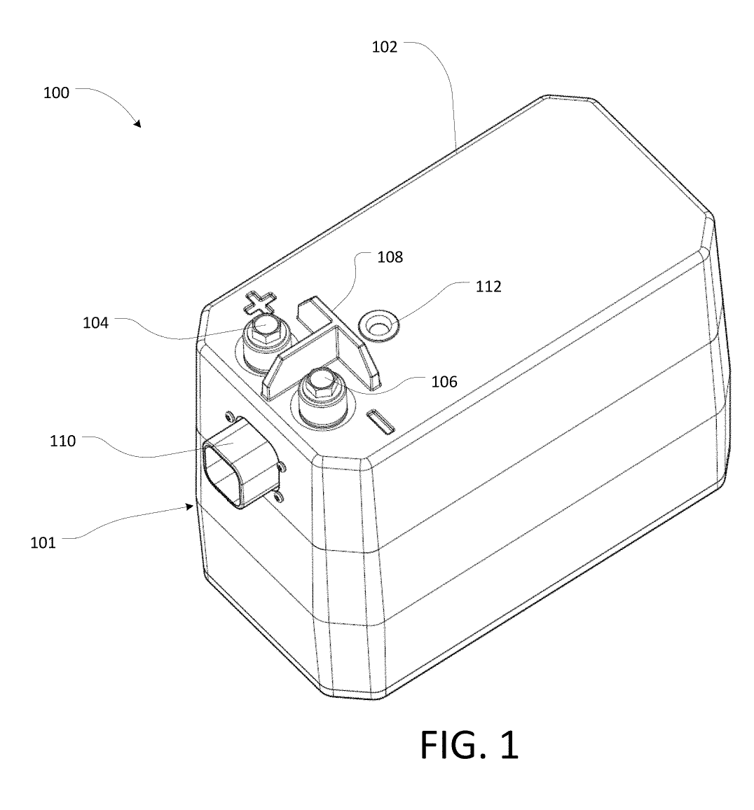

FIG. 1 is a top perspective view of an assembled battery 100 in accordance with an exemplary embodiment. The exterior of the lid 102 of the battery housing 101 includes a positive terminal post 104, a negative terminal post 106, a terminal post protection structure 108, a CAN connector 110, and a pressure vent 112. The positive terminal post 104 and negative terminal post 106 are connected to the interior components via internal bus bars and circuitry as described with reference to FIGS. 1 and 2.

The terminal post protection structure 108 may be formed as a single piece with the housing lid, for example, by molding or 3D printing. The protection structure 108 may be provided in order to protect the terminal posts 104 and 106 from unintentional or harmful contact. In addition, the protection structure 108 can prevent inadvertent creation of a short circuit between the terminal posts 104 and 106. For example, if a vehicle owner or mechanic drops a metal tool across the terminal posts 104 and 106 while performing maintenance, a short circuit is created. If the owner or mechanic attempts to retrieve the tool while it is in contact with both posts 104 and 106, severe electric shock may result. Thus, the terminal post protection structure 108 should include a longitudinal portion raised in the transverse direction far enough that a straight metal tool cannot touch both terminal posts 104 and 106 at the same time.

The valve 112 may be a waterproof pressure relief valve, such as a GORE protective vent. A waterproof pressure relief valve may allow the pressure within the battery housing to equalize with the outside air pressure while preventing the low-humidity atmosphere within the battery 100 from being compromised. The valve 310 is described in greater detail with reference to FIG. 2.

FIG. 2 depicts a cross sectional view of an assembled battery 100 in accordance with an exemplary embodiment. The unitary battery housing 101 comprises a lid 102 and a lower portion including an upper housing body 114, a lower housing body 116, and a baseplate 118. The lid 102 includes the pressure vent 112, negative terminal post 106, terminal post protection structure 108, and an opening 109 for the CAN connector 110, as shown in the exterior view of FIG. 1.

Within the housing 101, the CAN connector 110 may be in electrical communication with a monitoring and control PCB 120. The terminal post 106 is in electrical contact with a bus bar 122. Battery connection circuitry 144 in electrical contact with the bus bar 122 is further connected electrically to a plurality of electrochemical cells 124. A desiccant holder 126 may also be located within the housing 101.

The cross sectional view of FIG. 2 illustrates several advantages of the battery 100 over conventional designs. The unitary housing 101 provides a sealed environment for all internal components of the battery 100. In many existing automotive battery designs, the battery components are held in place by an internal structure, with an additional external protective structure, or blast shield, required to protect the battery 100 and maintain the desired interior conditions. Instead, the present battery housing 101 may contain integrated interior structural components to eliminate the need for additional interior components. For example, the lower housing body 116 described above may include an integrated lower cell holder framework 128, comprising an array of cylindrical openings sized to secure one end of each of the electrochemical cells 124. Similarly, the upper housing body 114 described above may include an integrated upper cell holder framework 130, comprising an array of cylindrical openings sized and arranged identically to the openings of the lower cell holder framework 128, so as to secure the opposite end of each of the electrochemical cells 124. Thus, the cells 124 may be held in place within the housing 101. In some embodiments, the portion of the lower space surrounding the cells 124 may be filled with an electronics potting compound to further secure the cells 124 in place and/or to reduce the effects of vibrations or other mechanical stresses on the battery 100. The potting compound may be any suitable gelatinous or solid compound, such as a silicone or other rubber gel, thermal setting plastics, epoxy, or the like.

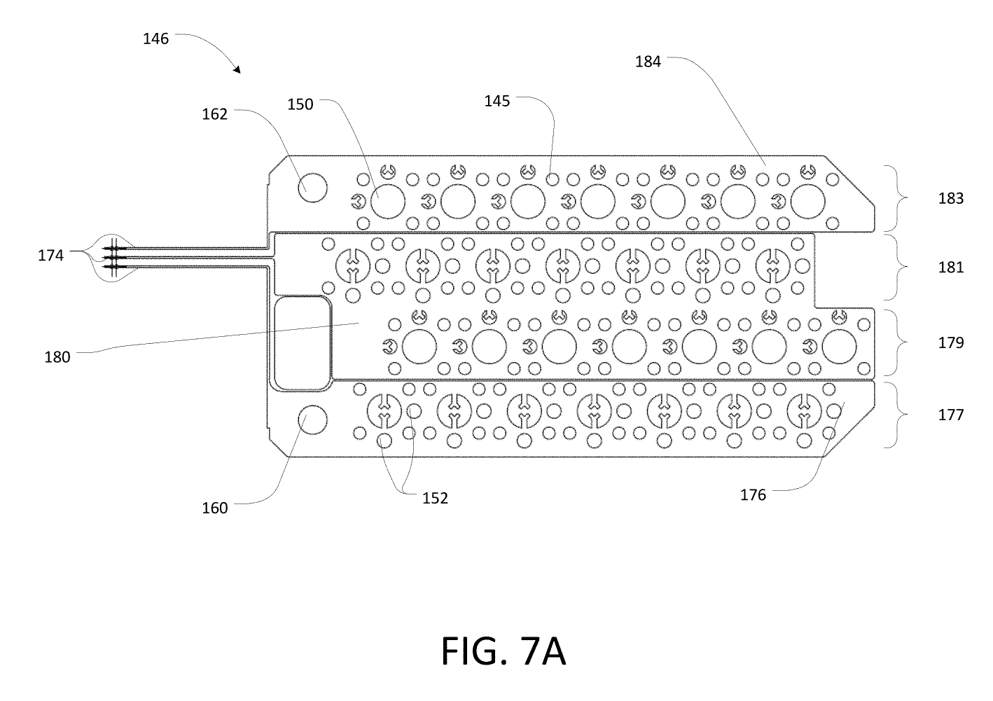

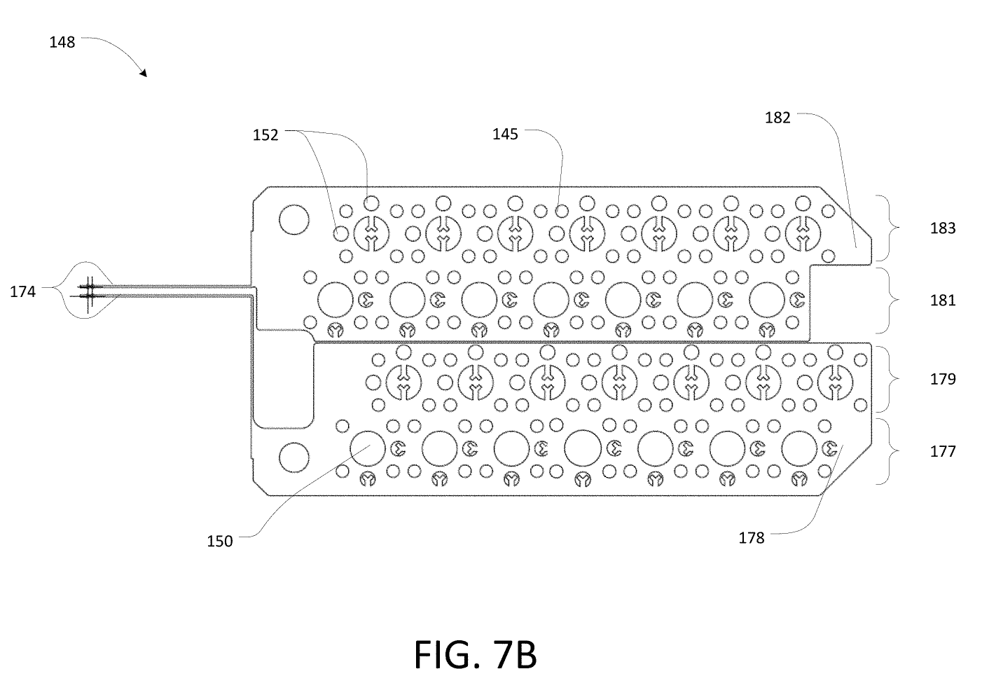

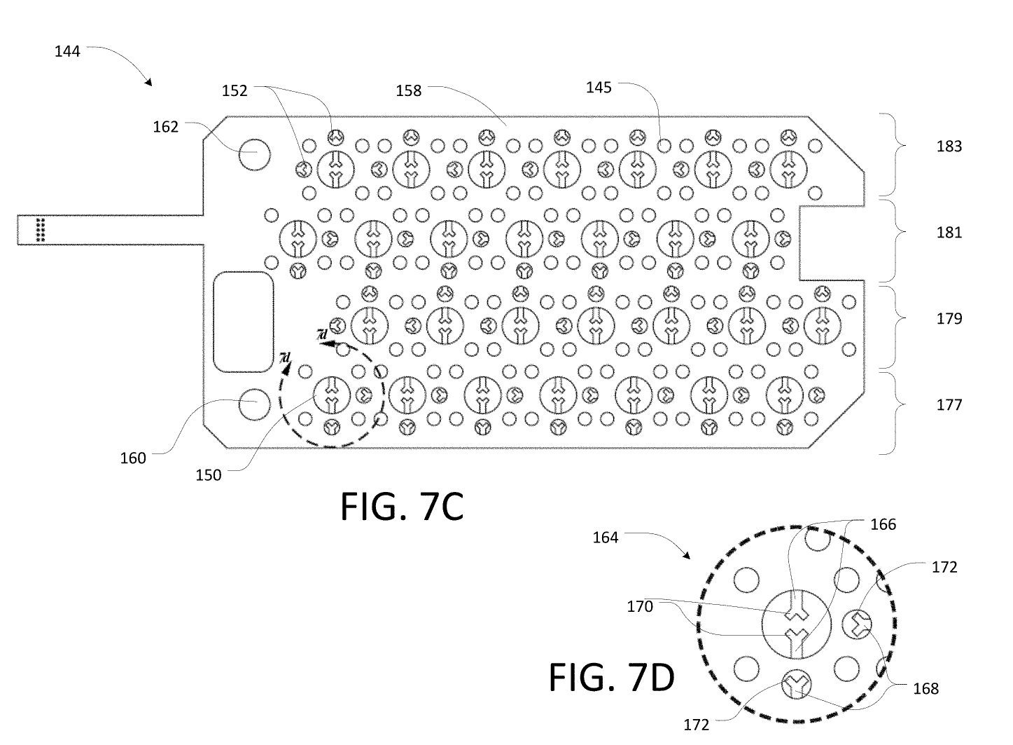

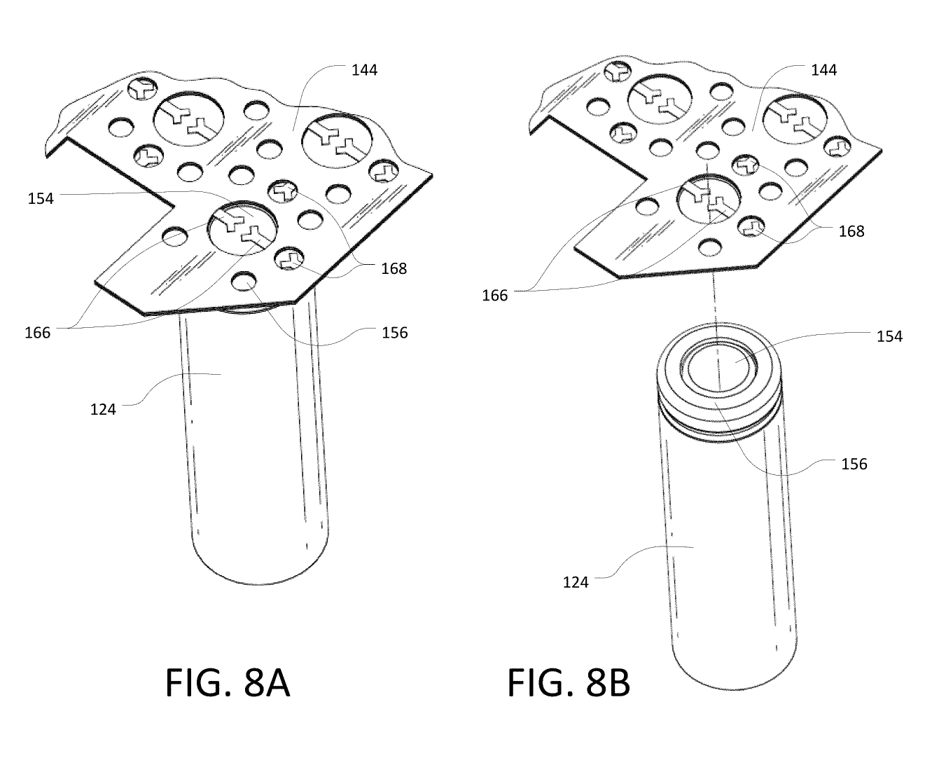

The battery connection circuitry 144 may be a flex circuit or similar substantially flat circuitry, and can be used to connect the terminals of the electrochemical cells 124 into a single battery circuit, especially in embodiments using cells 124 having both positive and negative terminals located on the same end of each cylindrical cell. Where both terminals of each cell are located at the same end, a single flex circuit 144 may provide the electrical connection to all cells 124. In some embodiments, the upper cell holder framework 130 may also serve as a support surface for the battery connection circuitry 144. Battery connection circuitry 144 is described in greater detail with reference to FIGS. 7A-8B.

The battery housing 101 will preferably be sealed or substantially sealed at all joints and ports so as to provide a stable environment for the electrochemical cells 124. Pressure and humidity variations may have significant detrimental effects on the battery 100. More specifically, the interior of the battery 100 should be kept at substantially the same pressure as the ambient air pressure to avoid excessive wear to the battery housing, seals, or other components. The interior of the housing 101 should also be kept relatively dry, as condensation or excess humidity may shorten battery life. Thus, a combination of environmental features may be provided to optimize moisture and pressure conditions within the battery 100.

Environmental control features may include a waterproof pressure relief valve 112, such as a GORE protective vent, and/or a desiccant contained within the desiccant holder 126. The waterproof pressure relief valve 112 may allow the pressure within the battery housing 101 to equalize with the outside air pressure while preventing liquids from entering the battery 100. Although some moisture may enter the battery 100 as air passes through the waterproof valve 112, the moisture may be removed within the battery 100 by a desiccant in the desiccant holder 126.

The desiccant within the battery housing 101 can be configured to absorb any moisture initially inside the housing 101 after manufacture, and may later absorb moisture from the air entering the battery housing 101 through the waterproof pressure valve 126 or a crack or hole in the material of the housing 101. In some embodiments, the upper cell holder framework 130 may also serve as a support for the desiccant holder 126. The desiccant holder 126 may be located near the cells 124 within the battery housing 101 so as to most effectively dry the air around the cells 124. However, the desiccant holder may be effective if located in any location within the battery housing 101.

The desiccant within the desiccant holder 126 may include a variety of desiccating or hygroscopic materials, such as silica gel, calcium sulfate, calcium chloride, activated charcoal, zeolites, Drierite, or any other suitable desiccant.

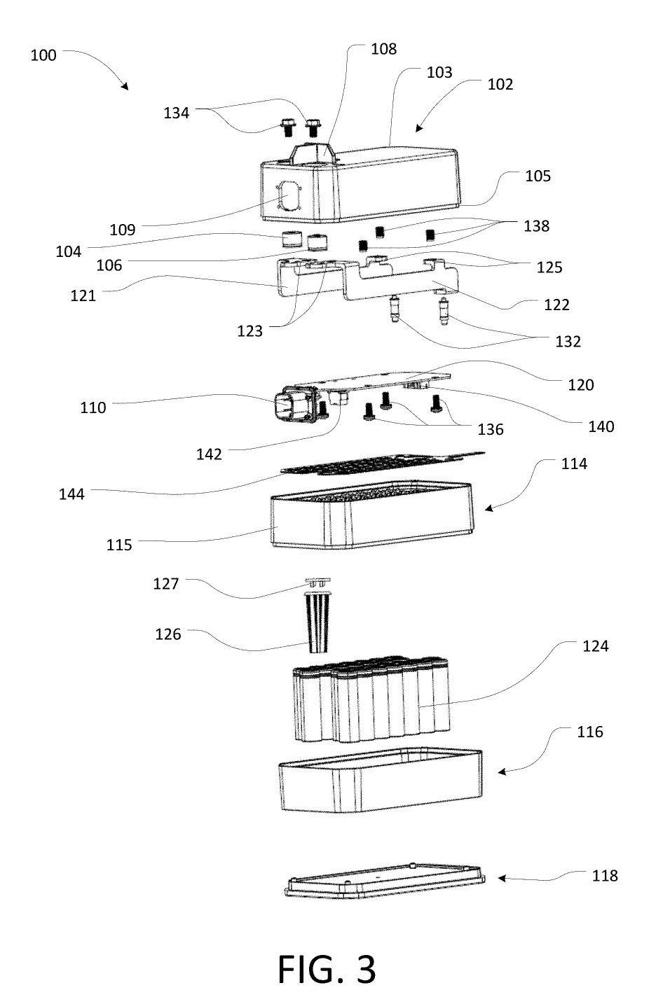

FIG. 3 depicts an exploded view of the automotive battery 100 expanded along the transverse axis. As shown, the battery 100 includes a plurality of electrochemical cells 124 contained within a housing comprising a housing lid 102, an upper housing body 114, a lower housing body 116, and a housing baseplate 118, which can be joined, sealed, or welded to form a unitary battery housing. The upper housing body 114 has an upper edge 115. The lid 102 has an upper surface 103 and a lower edge 105. During manufacturing, the upper edge 115 of the upper housing body may be sealingly fitted into, around, or against the lower edge 105 of the lid 102. Such a seal may be formed, for example, using an appropriate sealant, adhesive, weld, vibratory weld, and the like. The lid 102 includes terminal post protection structure 108 on its upper surface 103.

The housing may further contain a desiccant holder 126. A desiccant holder cover 127 may help contain the desiccant within the desiccant holder 126. Such a cap 127 may removably coupled to the desiccant holder 126 via a snap-fit, screw-fit, or other similar configuration.

Continuing with FIG. 3, a positive bus bar 121 and a negative bus bar 122 are disposed within the upper housing body 114 and/or the lid 102, and in electrical contact with the electrochemical cells 124 via connecting pins 132 and battery connection circuitry 144. Terminal posts 104 and 106 extend through the housing lid 102 to the exterior of the battery 100 and are in electrical communication with the positive bus bar 121 and the negative bus bar 122. The terminal posts 104 and 106 are secured by terminal post fasteners 134. The bus bars 121 and 122 may be held to the lid 102 by flanges 123 and 125 and secured with fasteners 136 and inserts 138. Monitoring and control printed circuit board (PCB) 120 is disposed within an upper portion of the housing and may be configured to monitor the actual voltage across each cell 124 or a set of cells 124, or to monitor the current flowing into or out of the battery 100 through bus bars 121 and 122. The PCB may include elements such as a terminal power header 140 and a thermistor connector 142. The PCB 120 is in electrical communication with the CAN connector 110 which extends through the housing lid 102 at opening 109 to the exterior of the battery 100. The PCB 120 may be supported in place by the CAN connector 110 as well as by the lid 102 and/or bus bars 121 and 122, and may be secured to the lid 102 and/or bus bars 121 and 122 by fasteners 136.

The electrochemical cells 124 are configured to provide direct current power. In some embodiments, the cells 124 may provide sufficient voltage to power a nominal 12-volt automotive power system. The cells 124 may be any variety of electrochemical cell, such as lithium ion, nickel metal hydride, lead acid, or the like. In some embodiments with multiple electrochemical cells 124, the cells 124 may be arranged in any combination of parallel and series connections. For example, a battery delivering a maximum of 15.6 volts may include a single string of four 3.9-volt cells connected in series, multiple 4-cell serial strings connected in parallel, or four serially connected strings of multiple parallel cells, so as to provide a greater energy storage capacity at the same voltage of 15.6 volts.

The housing components 102, 114, 116, and 118 may be assembled at various times during manufacturing to form one housing structure. In some embodiments, housing components 102, 114, 116, and 118 may be glued or otherwise adhered together to form a single housing unit. In embodiments where the housing components are made of a plastic, the housing components may be joined by any suitable variety of plastic welding, such as hot gas welding, hot plate welding, contact welding, speed tip welding, laser welding, solvent welding, or the like, to form a robust protective housing. In some embodiments, the housing may be an integrated unit containing internal structure such as compartments for the electrochemical cells 124, so as to avoid the additional weight and complexity associated with having separate internal structural components.

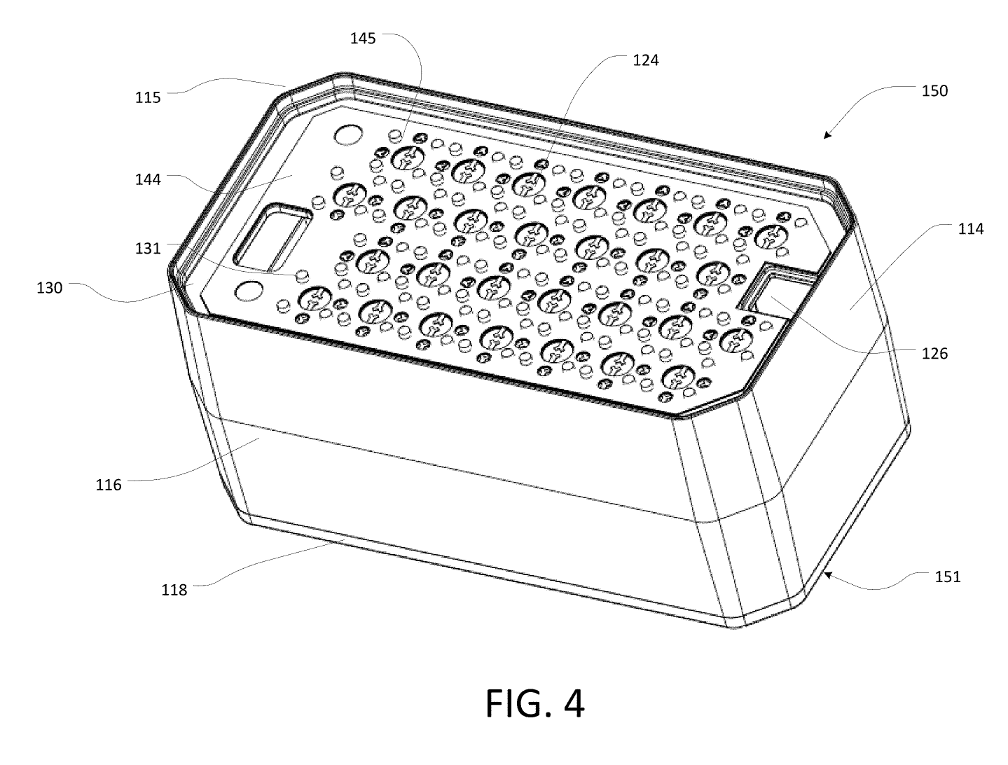

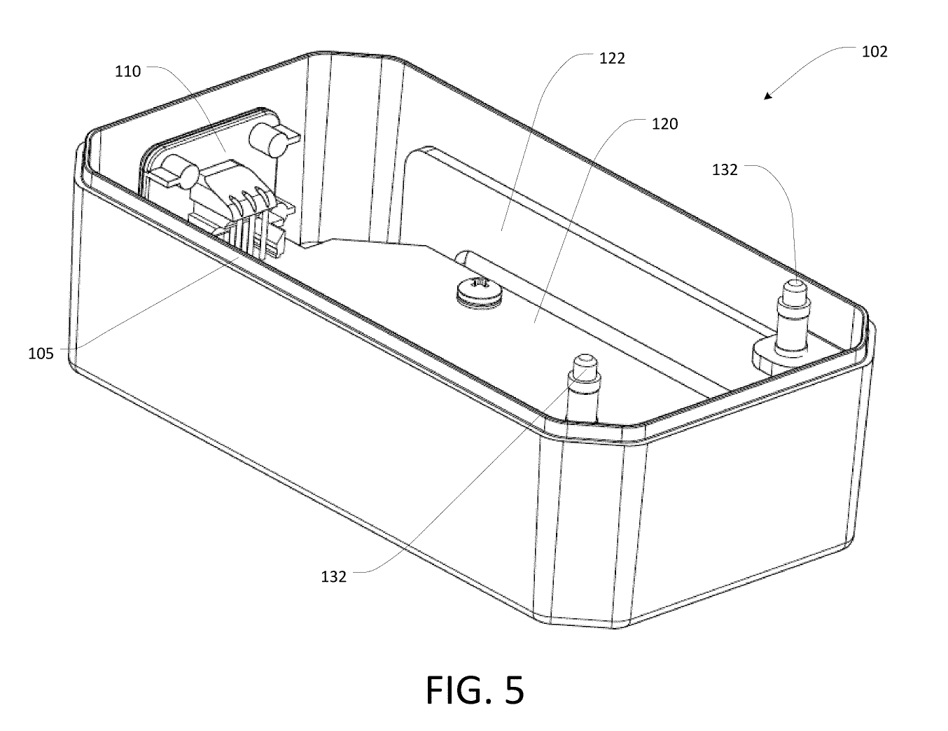

With reference to FIGS. 4 and 5, a simplified battery assembly process will now be described. In some aspects, the simplicity and efficiency of the battery assembly process are a result of various battery features described elsewhere herein. FIG. 4 depicts a lower portion 150 of a battery before final assembly. FIG. 5 depicts a lid 102 of a battery before final assembly, in an inverted orientation. A lower portion housing 151 may include the housing components 114, 116, and 118 described above, and may be manufactured with an upper interior framework 130 and lower interior framework 128 (not shown) for holding a plurality of electrochemical cells 124 and a desiccant holder 126, as described above with reference to FIGS. 2 and 3.

The lid 102 may be prepared for assembly by securing a negative bus bar 122 and a positive bus bar 121 (not shown) within the lid 102 with positive and negative terminal posts 104 (not shown) and 106 (not shown) connected to the bus bars 121 (not shown) and 122, and extending through the housing lid 102. Each bus bar has a connecting pin 132 configured to connect with circuitry of the lower portion 150 of the battery during assembly. A PCB 120 for battery monitoring and control may then be secured to the housing lid 102 and/or bus bars 121 (not shown) and 122 with a CAN connector 110 connecting to the PCB 120 through the housing lid 102.

With a completed battery lid 102 and lower battery portion 150, final assembly of the battery is straightforward and suitable for completion on an assembly line or similar high-capacity production line. The plurality of electrochemical cells 124 are inserted into the cylindrical openings in the interior framework 130 of the lower portion housing 151, and a desiccant holder 124 containing desiccant is inserted into the appropriate opening. Battery connection circuitry 144 configured to connect the cells 124 to the bus bars 121 and 122 may be placed on top of the cells 124. The interior framework 130 may further include circuitry alignment posts 131, configured to extend through corresponding holes 145 of the battery connection circuitry 144. In some embodiments, the battery connection circuitry 144 may be secured in place by melting upper portions of the circuitry alignment posts 131 and/or by securing the circuitry 144 to the alignment posts 131 with an adhesive.

In a final assembly step, the lid 102 is turned upright, placed atop the lower portion 150 and pressed downward to couple the lower edge 105 of the housing lid to the upper edge 115 of the lower portion housing 151. At the same time, bus bar connecting pins 132 will form a press-fit connection to the battery connection circuitry 144 of the lower portion 150, completing the electrical connection between the terminal posts and the electrochemical cells 124 via the bus bars 121 and 122, connecting pins 132, and other circuitry. The housing lid 102 and lower portion housing 151 are sealed at their intersection by any suitable form of plastic welding to complete the assembly.

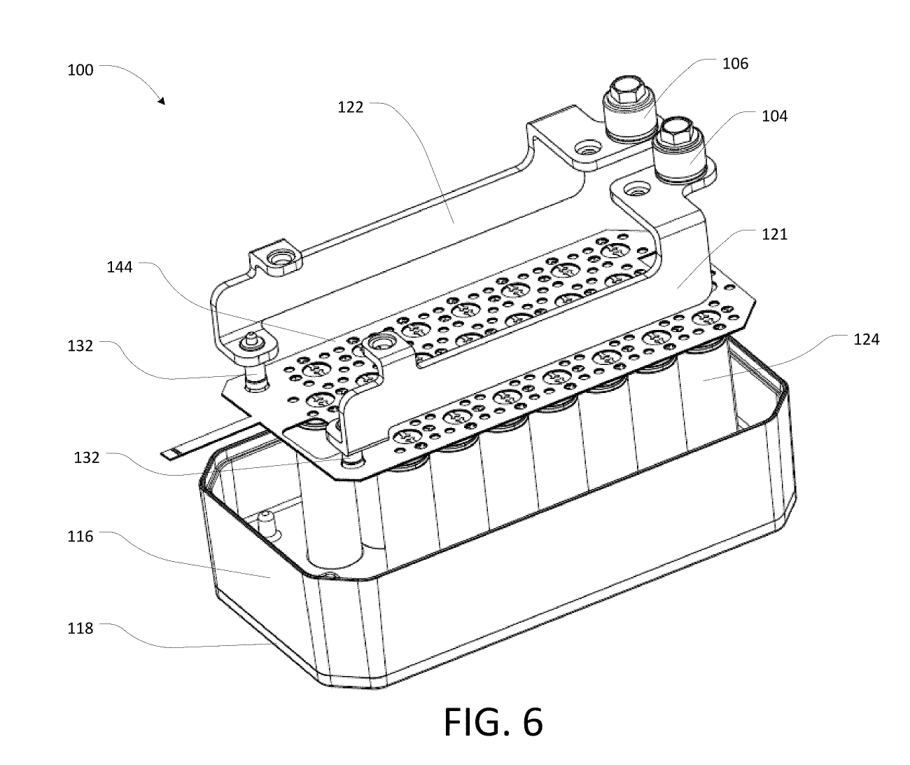

FIG. 6 depicts a cutaway view of a battery 100 showing only the primary electrical connections of the battery 100 after final assembly. As used herein, the term “primary electrical connections” of the battery 100 refers to the conductive path between the electrochemical cells 124 and the terminal posts 104 and 106, by which the electrochemical cells 124 provide nominal 12 volt electrical power to various vehicle systems. Thus, the primary electrical connections do not include other conductive connections to the battery circuit such as control or monitoring systems. The primary electrical connections include the electrochemical cells 124, connecting pins 132, bus bars 121 and 122, terminal posts 104 and 106, and battery connection circuitry 144 connecting the cells 124 to the connecting pins 132. For clarity, the baseplate 118 and lower housing body 116 are also depicted. Thus, current can flow between the negative terminal post 106 and the negative terminal of the cells 124 by traveling through the negative bus bar 122, connecting pin 132, and battery connection circuitry 144. Similarly, current can flow between the positive terminal of the cells 124 and the positive terminal post 104 by traveling through the battery connection circuitry 144, connecting pin 132, and positive bus bar 121.

The battery connection circuitry 144 will now be described in greater detail with reference to FIGS. 7A-8B. In some embodiments, both the positive and negative terminals of a cylindrical electrochemical cell 124 may be located on the same end surface of the cell 124. In at least these embodiments, a flex circuit 144 or other substantially flat circuitry may be used to connect each cell 124 electrically with other cells 124 of the battery 100 and with bus bars 121 and 122 or any other circuitry configured to carry current into and out of the battery 100. In some embodiments, the battery connection circuitry 144 may be a single layer or multilayer flex circuit. For example, a multilayer flex circuit 144 in this context may have at least two conductive layers 146 and 148 separated by electrically insulating materials such as polyimides, PET, PEEK, or Kapton. In some embodiments, each layer 146, 148 may be further divided into a plurality of conducting surface areas separated by space or by an electrically insulating material. In some embodiments, the flex circuit 144 may have a single layer divided into a plurality of conducting surface areas.

Electrochemical cells compatible with the exemplary flex circuit 144 depicted in FIGS. 7A-7C may be cylindrical cells, with both the positive terminal 154 and the negative terminal 156 located on the same circular end face of the cell 124. The positive terminal 154 may be generally circular and located nearer to the center of the end face of the cell 124, while the negative terminal 156 may be in the general shape of a ring around the exterior closer to the perimeter edge of the end face of the cell 124.

With reference to FIGS. 7A-7C, the two conductive layers 146 and 148 of the flex circuit 144 may include a positive opening 150 for each electrochemical cell 124. The positive opening may be sized and shaped to provide access to the positive terminal of the cell 124. The conductive layers 146, 148 may also include negative openings 152. As shown in FIGS. 7A-7C, at least two negative openings 152 are provided for each cell 124. The negative openings 152 are sized and shaped to provide access to portions of the negative terminal of the cell 124. In general, the positive openings 150 and the negative openings 152 are disposed in approximately the same location on each of the two conductive layers 146 and 148 so that the layers may be stacked together with an insulating layer between them to form a single battery connection circuit 144. While the flex circuits described herein include positive and negative openings, in some embodiments, a single opening is provided for each cell. That is to say, the electrical contacts of the flex circuit which contact the positive and negative terminals of the cells may extend into a single shared opening.

As shown in FIG. 7A, the first conductive layer 146 may further include connection points 160 and 162 for connecting the flex circuit 144 to one or more bus bar or other battery circuitry. Additional monitoring connections 174 may extend from each conductive surface (e.g., 176, 180 & 184 in FIG. 7A) to battery monitoring circuitry for voltage measurements or other diagnostics. In some embodiments, the monitoring connections 174 may be connected to circuitry on the battery monitoring printed circuit board 120 described elsewhere herein.

Continuing with FIGS. 7A and 7B, the exemplary flex circuit 144 is configured to connect twenty-eight individual electrochemical cells 124 in four sets of seven parallel cells 124, the four sets connected in series. A positive bus bar (not shown) may be connected to the positive connection point 160 of the flex circuit 144. The positive connection point 160 may be connected to the positive terminals of the first set 177 of seven cells (not shown) by a first conductive surface 176 in the first conductive layer 146. The negative terminals of the first set 177 of seven cells (not shown) may be connected to the positive terminals of the second set 179 of cells (not shown) by a second conductive surface 178 in the second conductive layer 148. The negative terminals of the second set 179 of cells (not shown) may be connected to the positive terminals of the third set 181 of seven cells (not shown) by a third conductive surface 180 in the first conductive layer 146. The negative terminals of the third set 181 of seven cells (not shown) may be connected to the positive terminals of the fourth set 183 of seven cells (not shown) by a fourth conductive surface 182 in the second conductive layer 148. Finally, the negative terminals of the fourth set 183 of seven cells (not shown) may be connected to the negative connection point 162 and a negative bus bar (not shown) by a fifth conductive surface 184 in the first conductive layer 146. This arrangement of a battery circuit is an exemplary embodiment, and it is noted that various other arrangements of cells, conductive layers, and conductive surfaces may be designed and implemented with minimal experimentation required.

FIG. 7C shows an assembled battery connection flex circuit 144 including the conductive layers 146 and 148 of FIGS. 7A and 7B. In FIG. 7C, battery connection circuit 144 includes conductive layers 146 and 148. Flex circuit 144 may also include three layers of insulating material. A middle layer of insulating material (not shown) is preferably placed between conductive layers 146 and 148 to maintain electrical insulation between all conductive surfaces. A lower insulating layer (not shown) may be included below the lower conductive layer 146, and an upper insulating layer 158 may be included above the upper conductive layer 148 to protect the conductive layers from unexpected electrical contact with other battery components. The insulating layers may be of substantially the same dimensions as conductive layers 146 and 148 so that the positive openings 150, negative openings 152, and circuitry alignment holes 145 are maintained through all layers. The second conductive layer 148 and all insulating layers may include openings at the location of the connection points 160 and 162 on the lower conductive layer 146.

FIG. 7D is a detail view of a portion 164 of the assembled flex circuit 144. The portion 164 is configured to provide the electrical connections between the flex circuit 144 and a single electrochemical cell. As described above, the upper circular face of an electrochemical cell compatible with the flex circuit 144 may include a central positive terminal 154 surrounded by a ring-shaped negative terminal 156. A plurality of connecting arms 166, 168 may connect the terminals 154, 156 to the conductive layers of the flex circuit 144. Positive connecting arms 166 may be connected at one end to an edge of a positive opening 150. The other end of each positive connecting arm 166 may include at least one positive connection point 170 configured to make electrical contact with the positive terminal 154 of an electrochemical cell. Similarly, negative connecting arms 168 may be connected at one end to an edge of a negative opening 152, with the other end containing at least one negative connection point 172 configured to make electrical contact with the negative terminal 156 of an electrochemical cell. The positive connecting arms 166 for a cell may be insulated from the negative arms 168 for the same cell, for example, by being located on separate conductive layers 146 and 148.

As best shown in FIG. 7D, the positive connecting arms 166 and/or the negative connecting arms 168 may include a first end that extends from a conducting layer in the circuit and into an opening through the circuit and/or one or more conducting layers. The connecting arms 166, 168 may include a Y-shaped branch that allows the connecting arms to have at least two contact points with the cell. Thus, as shown in FIG. 7D, the positive conducting layer may be electrically connected to the positive terminal of the cell at at least four distinct points (e.g., a point under each Y-shaped branch). Similarly, the negative conducting layer may be electrically connected to the negative terminal of the cell at at least four distinct points. More branches in the connecting arms may be used to create additional contact points with the cells. Multiple contacts points with the cell terminals may help prevent the contacts from disconnecting with the cell terminals when the battery is subjected to vibration and/or impact experienced while, for example, driving an electric vehicle. One or more welds may be used to secure the connecting arms 166, 168 to the cell and/or contact points to the cell terminals.

It is to be understood that while there are separate positive and negative openings shown in, for example, FIGS. 7C-7D, a single opening for each cell may be provided. In some aspects, having dedicated openings for the positive terminals and the negative terminals may help prevent electrical shorts. A plurality of smaller openings may also reduce weight and/or improve the flexibility of the circuit.

During battery operation, some vibration or motion may be encountered, for example, due to motion of the vehicle or other source of vibration or motion. In some cases, vibration or motion may cause an electrochemical cell 124 to temporarily lose contact with a connection arm 166, 168, possibly disrupting operation or reducing battery performance. Vibration-related connection difficulties may be mitigated by employing multiple connection arms 166, 168 and/or multiple connection points 170, 172 to provide redundant connections. In the configuration of FIG. 7D, two connection arms 166, 168 are provided for each terminal. In addition, each connection arm 166, 168 has connection points 170, 172 in the form of y-shaped branches, which provide for multiple points of contact with the surface of a cell 124. Thus, at least one positive and at least one negative point of contact with the terminals 154, 156 can be maintained despite any vibration or shifting of the cells 124 in the longitudinal or transverse direction relative to the flex circuit 144.

FIG. 8A is a top perspective view of a portion of the assembled flex circuit 144 of FIG. 7C showing the electrical connections between the flex circuit 144 and an electrochemical cell 124 in accordance with an exemplary embodiment. FIG. 8B shows the same operative configuration of a cell 124 and a portion of the flex circuit 144 in an exploded view. The cell 124 has a circular positive terminal 154 located near the center of the upper circular end face, and a perimeter ring-shaped negative terminal 156 surrounding the positive terminal 154. The terminals may be separated by a layer of insulating material. The flex circuit 144 may connect to both the positive terminal 154 and the negative terminal 156 of the cell 124 by being placed and/or secured against the upper surface of the cell 124. As described with reference to FIGS. 7A-7D, positive connection arms 166 extend from a conductive layer of the flex circuit 144 to make contact at multiple contact points with the positive terminal 154 of the cell 124. Similarly, negative connection arms 168 extend from the other conductive layer of the flex circuit 144 to make contact at multiple contact points with the negative terminal 156 of the cell 124.

The foregoing description details certain embodiments of the systems, devices, and methods disclosed herein. It will be appreciated, however, that no matter how detailed the foregoing appears in text, the devices and methods can be practiced in many ways. As is also stated above, it should be noted that the use of particular terminology when describing certain features or aspects of the invention should not be taken to imply that the terminology is being re-defined herein to be restricted to including any specific characteristics of the features or aspects of the technology with which that terminology is associated. The scope of the disclosure should therefore be construed in accordance with the appended claims and any equivalents thereof.

With respect to the use of any plural and/or singular terms herein, those having skill in the art can translate from the plural to the singular and/or from the singular to the plural as is appropriate to the context and/or application. The various singular/plural permutations may be expressly set forth herein for sake of clarity.

It is noted that the examples may be described as a process. Although the operations may be described as a sequential process, many of the operations can be performed in parallel, or concurrently, and the process can be repeated. In addition, the order of the operations may be rearranged. A process is terminated when its operations are completed. A process may correspond to a method, a function, a procedure, a subroutine, a subprogram, etc.

The previous description of the disclosed implementations is provided to enable any person skilled in the art to make or use the present disclosed process and system. Various modifications to these implementations will be readily apparent to those skilled in the art, and the generic principles defined herein may be applied to other implementations without departing from the spirit or scope of the disclosed process and system. Thus, the present disclosed process and system is not intended to be limited to the implementations shown herein but is to be accorded the widest scope consistent with the principles and novel features disclosed herein.

What is claimed is:

1. A low voltage battery for an electric vehicle, the battery comprising:
a housing;
a plurality of rechargeable electrochemical cells disposed within the housing, the electrochemical cells having a top side and a bottom side, the top side having at least one positive terminal and at least one negative terminal disposed thereon;
a positive bus bar disposed within the housing;
a negative bus bar disposed within the housing;
a positive terminal post in electrical contact with the positive bus bar and extending through the housing;
a negative terminal post in electrical contact with the negative bus bar and extending through the housing; and
a flex circuit comprising:
a first conductive surface in electrical contact with the positive bus bar and the positive terminal of at least one of the electrochemical cells; and
a second conductive surface in electrical contact with the negative bus bar and the negative terminal of at least one of the electrochemical cells;
wherein the second conductive surface is insulated from electrical contact with the first conductive surface.

2. The battery of claim 1, wherein the second conductive surface is insulated from electrical contact with the first conductive surface by an electrically insulating material.

3. The battery of claim 2, wherein the flex circuit comprises a first layer of electrically conductive material and a second layer of electrically conductive material, the first conductive surface being located on the first layer of conductive material, the second conductive surface being located on the second layer of conductive material, and wherein a layer of electrically insulating material is disposed between the first layer and the second layer.

4. The battery of claim 1, further comprising battery monitoring circuitry disposed within the housing, the battery monitoring circuitry electrically connected to the first conductive surface and the second conductive surface.

5. The battery of claim 4, wherein the battery monitoring circuitry is configured to measure a voltage drop between the first conductive surface and the second conductive surface.

6. A flexible circuit for a vehicle battery, the circuit comprising:
at least a first conductive layer and a second conductive layer that are electrically separated by an insulating layer;
at least one opening in the first conductive layer, the opening sized and shaped to provide access to at least a portion of a positive terminal of an electrochemical cell;
a plurality of electrically conductive positive contact arms extending from the first conductive surface and into the at least one opening in the first conductive layer, the positive contact arms including at least one positive contact point configured to contact and electrically connect at least one positive terminal of an electrochemical cell;
at least one opening in the second conductive layer, the opening sized and shaped to provide access to at least a portion of a negative terminal of an electrochemical cell; and
a plurality of electrically conductive negative contact arms extending from the second conductive surface and into the at least one opening in the second conductive layer, the negative contact arms including at least one negative contact point configured to contact and electrically connect to at least one negative terminal of the electrochemical cell.

7. The circuit of claim 6, wherein each positive contact arm includes a first end and a second end, the first end extending from an edge that defines at least one of the openings in the first conductive layer and the second end configured to contact and electrically connect the positive terminal of the electrochemical cell.

8. The circuit of claim 7, wherein the second ends include a plurality of contact points configured to contact and electrically connect to the positive terminal of the electrochemical cell.

9. The circuit of claim 8, wherein the second ends branch into a Y-shaped portion having at least two contact points configured to contact and electrically connect to the positive terminal of the electrochemical cell.

10. The circuit of claim 9, wherein the negative contact arms include a first end and a second end, the first end extending from an edge that defines at least one of the openings in the second conductive layer and the second end configured to contact and electrically connect to the negative terminal of the electrochemical cell.

11. The circuit of claim 10, wherein the second ends of the negative contact arms include a plurality of contact points configured to contact and electrically connect to the negative terminal of the electrochemical cell.

12. The circuit of claim 11, wherein the second ends of the negative contact arms branch into a Y-shaped portion having at least two contact points configured to contact and electrically connect to the negative terminal of the electrochemical cell.

13. The circuit of claim 6, wherein the second conductive surface includes at least two negative openings for each electrochemical cell.

14. The circuit of claim 6, wherein the first conductive surface is configured to electrically connect at least two cells in series.

15. The circuit of claim 6, wherein the first conductive surface is configured to electrically connect at least two sets cells of in parallel, the at least two sets of cells each including at least two cells connected in series.

16. A method of manufacturing a vehicle battery, the method comprising:
placing a plurality of rechargeable electrochemical cells into a first housing portion, the electrochemical cells having a top side and a bottom side, the top side having at least one positive terminal and at least one negative terminal disposed thereon;
securing a positive bus bar and a negative bus bar to a second housing portion that is different from the first housing portion, the positive bus bar connected to a positive terminal post extending through the second housing portion, the negative bus bar connected to a negative terminal post extending through the second housing portion;
electrically connecting the cells by placing a flex circuit against the top side of the cells, the flex circuit comprising:
a first conductive surface in electrical contact with the positive terminal of at least one of the electrochemical cells; and
a second conductive surface in electrical contact with the negative terminal of at least one of the electrochemical cells;
wherein the second conductive surface is insulated from electrical contact with the first conductive surface;
contacting the first and second housing portions such that the positive bus bar contacts and forms a direct electrical connection with the first conductive surface, and the negative bus bar contacts and forms a direct electrical connection with the second conductive surface; and
sealing the first housing portion to the second housing portion.

17. The method of claim 16, further comprising securing the flex circuit in place against the top side of the cells.

18. The method of claim 17, wherein securing the flex circuit in place comprises applying an adhesive compound to at least a portion of the flex circuit.

19. The method of claim 17, wherein securing the flex circuit in place comprises plastic welding at least a portion of the flex circuit.

20. The method of claim 17, wherein securing the flex circuit in place comprises welding at least one positive conducting arm to a positive terminal and at least one negative conducting arm to a negative terminal.
